(19) United States
(12) Patent Application Publication
(10) Pub. No.: US 2011/0080201 A1
(43) Pub. Date: Apr. 7, 2011

(54) DIGITAL LOGIC CIRCUITS HAVING A PULSE WIDTH TIMING CIRCUIT

(75) Inventors: Ping-Lin Yang, Tianzhong Township (TW); Yi-Tzu Chen, Hsinchu (TW)

(73) Assignee: TAIWAN SEMICONDUCTOR MANUFACTURING CO., LTD., Hsin-Chu (TW)

(21) Appl. No.: 12/574,998

(22) Filed: Oct. 7, 2009

(51) Int. Cl. H03K 5/04

(52) U.S. Cl. 327/172

(57) ABSTRACT

A pulse width timing includes a first complementary resistor-capacitor (RC) circuit having an input for receiving an input signal, and a second complementary RC circuit coupled to an output of the first complementary RC circuit, wherein the first and second complementary RC circuits cooperate to produce an output signal based on the input signal, the output signal being delayed and having an adjusted pulse width with respect to the input signal.

### TECHNICAL FIELD

The present disclosure is generally related to digital logic circuits and, more particularly, is related to digital logic circuits having a pulse width timing circuit.

### BACKGROUND

To generate a delayed and pulse width tunable pulse, a delay circuit is typically combined with a resistor-capacitor (RC) circuit. The capacitor charges and discharges, producing a delay time. With the resistor in the charge or the discharge path, the unbalanced charge and discharge paths cause the pulse to be skewed, which facilitates in producing a pulse width. The pulse width based on the RC circuit is typically not stable, exhibiting, for example, delay time variation and corner variation, which can cause operational or functional errors at the digital logic circuits. In electronic memory operation, for example, the read/write operation depends on the detection of the pulse width of the pulses, e.g., the row active signal. If the row active signal has delayed and pulse width tunable pulses that are unstable, the read/write operation may function improperly.

Desirable in the art is an improved pulse width timing circuit that reduces the delay time variation and/or corner variation.

### SUMMARY

A pulse width timing includes a first complementary resistor-capacitor (RC) circuit having an input for receiving an input signal, and a second complementary RC circuit coupled to an output of the first complementary RC circuit, wherein the first and second complementary RC circuits cooperate to produce an output signal based on the input signal, the output signal being delayed and having an adjusted pulse width with respect to the input signal.

The above and other features of the present invention will be better understood from the following detailed description of the preferred embodiments of the invention that is provided in connection with the accompanying drawings.

### BRIEF DESCRIPTION OF THE DRAWINGS

The accompanying drawings illustrate preferred embodiments of the invention, as well as other information pertinent to the disclosure, in which:

FIG. 1 is a block diagram that illustrates an embodiment of a system having a pulse width timing circuit;

FIG. 2 is a high-level block diagram that illustrates an embodiment of a pulse width timing circuit, such as that shown in FIG. 1;

FIG. 3 illustrates an embodiment of desirable pulse width signals from a pulse width timing circuit, such as that shown in FIG. 2;

FIG. 4 is a more detailed block diagram that illustrates an embodiment of a pulse width timing circuit, such as that shown in FIG. 2;

FIG. 5 illustrates an embodiment of pulse width signals from a pulse width timing circuit, such as that shown in FIG. 4;

FIG. 6 is a more detailed block diagram that illustrates another embodiment of a pulse width timing circuit, such as that shown in FIG. 4; and

FIG. 7 is a more detailed block diagram that illustrates another embodiment of a pulse width timing circuit, such as that shown in FIG. 4.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,” “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Exemplary systems are first discussed with reference to the figures. Although these systems are described in detail, they are provided for purposes of illustration only and various modifications are feasible. After the exemplary systems are described, examples of digital logic circuits having pulse width timing circuits are provided.

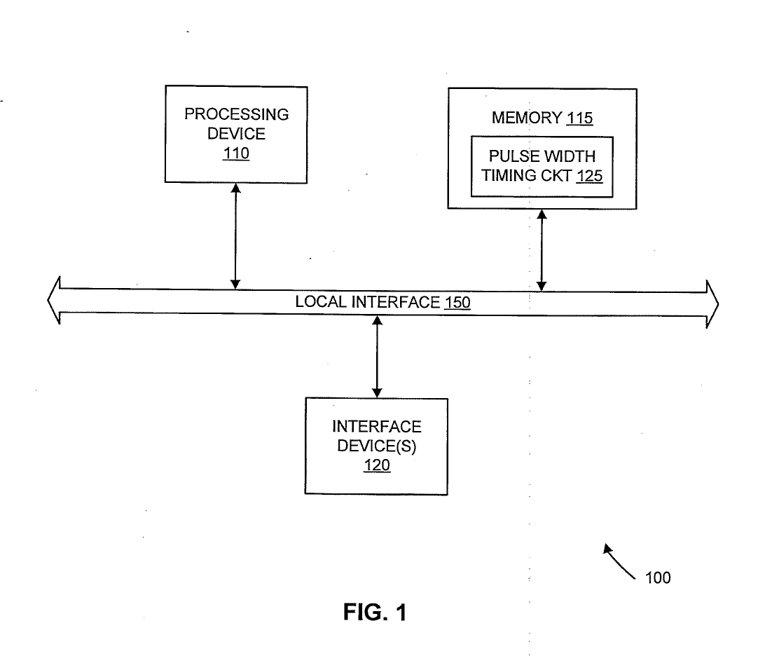

FIG. 1 is a block diagram that illustrates an embodiment of a system 100 having a pulse width timing circuit 125. The system 100 can be an exemplary architecture for a generic computer. The system 100 comprises a processing device 110, memory 115, and one or more user interface devices 120, each of which is connected to a local interface 150 (e.g., a bus). The processing device 110 can include any custom made or commercially available processor, a central processing unit (CPU) or an auxiliary processor among several processors associated with the generic computer, a semiconductor based microprocessor (in the form of a microchip), or a macroprocessor. The memory 115 can include any one or a combination of volatile memory elements (e.g., random access memory (RAM, such as DRAM, SRAM, etc.)) and nonvolatile memory elements (e.g., ROM, hard drive, tape, CDROM, etc.).

The one or more user interface devices 120 comprise those components with which the user (e.g., administrator) can interact with the system 100. Where the system 100 comprises a server computer or similar device, these components can comprise those typically used in conjunction with a PC such as a keyboard and mouse.

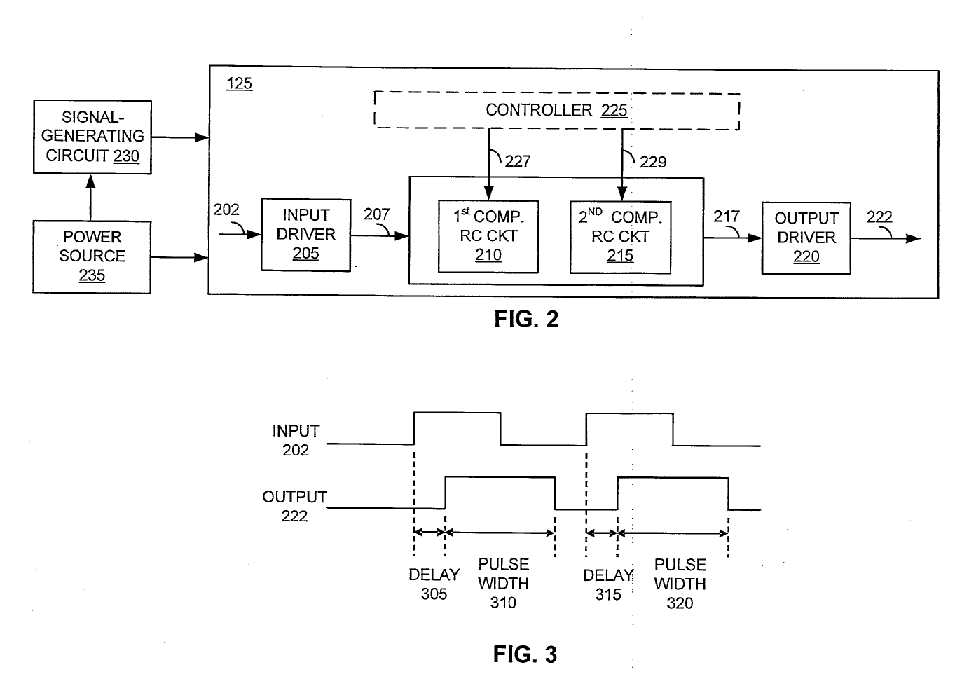

The memory 115 normally comprises various programs (in software and/or firmware) including an operating system (O/S). The O/S controls the execution of programs, and provides scheduling, input-output control, file and data management, memory management, and communication control and related services. The architecture of the memory 115 includes the pulse width timing circuit 125, which is further described in connection with FIGS. 2-6. It should be noted that although the pulse width timing circuit 125 is shown at the memory 115, the pulse width timing circuit 125 can be implemented at other digital logic circuits, such as the microprocessors, microcontrollers, and static RAM, among others. Also, the pulse width timing circuit 125 can be fabricated as an integrated circuit or as part of an integrated circuit.

FIG. 2 is a high-level block diagram that illustrates an embodiment of a pulse width timing circuit 125, such as that shown in FIG. 1. The pulse width timing circuit 125 receives an input signal and power from a signal-generating circuit 230 and a power source 235, respectively. The signal-generating circuit 230 also receives power from the power source 235.

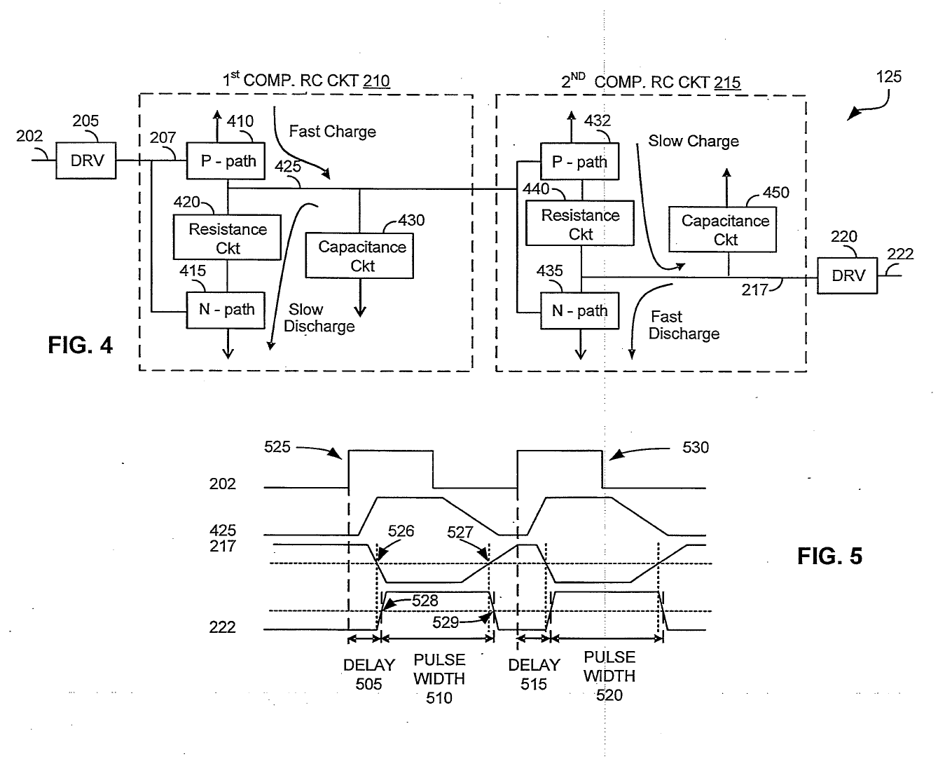

The pulse width timing circuit 125 includes an input driver 205 that receives the input signal via line 202 and maintains signal integrity of the input signal. A first complementary RC circuit 210 and second complementary RC circuit 215 receive the input signal from the input driver 205 via line 207. The first complementary RC circuit 210 and second complementary RC circuit 215 are designed to delay generating a pulse width signal based on the input signal and adjust the pulse width of the pulse width signal. The first complementary RC circuit 210 and second complementary RC circuit 215 are further described in connection with FIGS. 4, 6, and 7. Although FIG. 2 and the other FIGS. show a single set of complementary RC circuits 210, 215, multiple sets of complementary RC circuits can be implemented in the present disclosure.

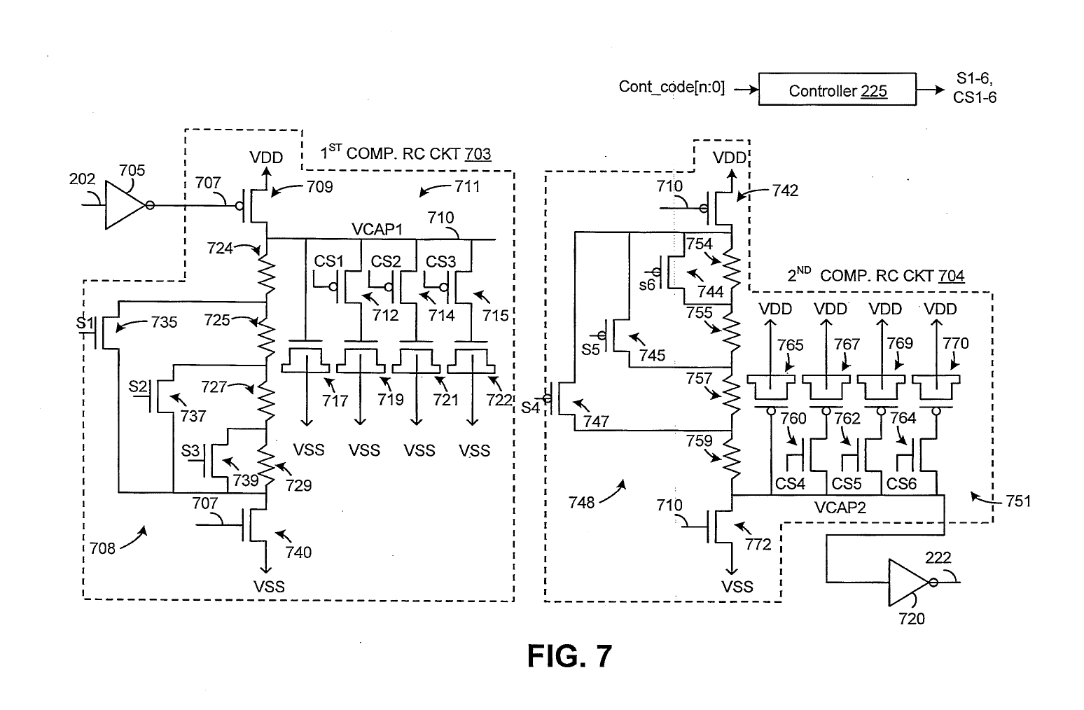

The pulse width timing circuit 125 further includes an output driver 220 that receives the pulse width signal via line 217 and maintains signal integrity of the pulse width signal via line 222. The input driver 205 and the output driver 220 can include, but are not limited to, inverters and buffers. Alternatively or additionally, the pulse width timing circuit 125 further includes a controller 225 that transmits control signals to the first complementary RC circuit 210 and second complementary RC circuit 215 via lines 227, 229, respectively. The controller 225 is further described in connection with FIG. 7.

FIG. 3 illustrates an embodiment of desirable pulse width signals from a pulse width timing circuit 125, such as that shown in FIG. 2. The input signal at line 202 can include, but is not limited to, a square waveform that can be manipulated to provide the desirable pulse width signals at line 222. The pulse width timing circuit 125 can delay generating the pulse width signals by a delay time 305, 315 and adjust the pulse width 310, 320 of the pulse width signals, shown at output line 222, based on the input signals at line 202. This is desirable for systems using a non 50% duty cycle stable delayed pulse and/or pulse width. For example, a row active control signal in memory 115 (FIG. 1) having a stable delay and pulse width can improve the read/write operation of memory 115.

FIG. 4 is a more detailed block diagram that illustrates an embodiment of a pulse width timing circuit 125, such as that shown in FIG. 2. The first complementary RC circuit 210 includes a first P-path circuit 410, first N-path circuit 415, first resistance circuit 420 and first capacitance circuit 430. The first resistance circuit 420 is coupled between the first P-path circuit 410 and first N-path circuit 415, and the first capacitance circuit 430 is coupled at a node between the first P-path circuit 410 and first resistance circuit 420.

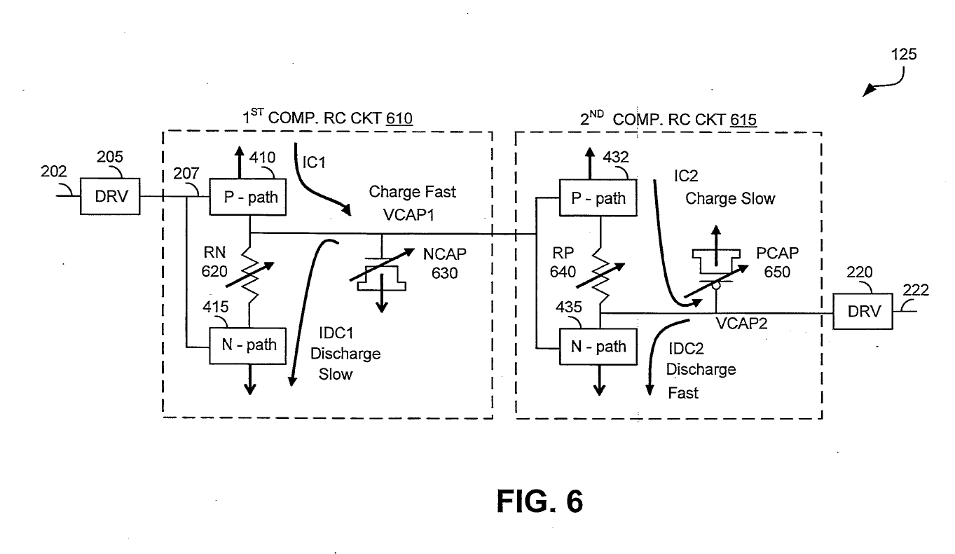

The second complementary RC circuit 215 includes a second P-path circuit 432, second N-path circuit 435, second resistance circuit 440, and second capacitance circuit 450. The second resistance circuit 440 is coupled between the second P-path circuit 432 and second N-path circuit 435 and the second capacitance circuit 450 is coupled at a node between the second resistance circuit 440 and second N-path circuit 435. In general, the first and second P-path circuits 410, 432 and the first and second N-path circuits 415, 435 can include, but are not limited to, PMOS transistors and NMOS transistors. The first and second resistance circuit 420, 440 and the first and second capacitance circuit 430, 450 can include fixed and/or variable electrical component(s) or a combination of both. In one embodiment, the first and second P-path circuits 410, 432 and the first and second N-path circuits 415, 435 are configured as CMOS inverters using PMOS and NMOS transistors that are coupled to RC circuits. The first complementary RC circuit 210 and second complementary RC circuit 215 are further described in connection with FIGS. 6 and 7.

The first complementary RC circuit 210 receives the input signal from the input driver 205 via line 207. The first complementary RC circuit 210 is designed to receive and pass the input signal to the first resistance circuit 420 and first capacitance circuit 430 of the first complementary RC circuit 210 using the first P-path circuit 410 and first N-path circuit 415. The first capacitance circuit 430 is rapidly charged by the first P-path circuit 410, and is slowly discharged by the first resistance circuit 420 and first N-path circuit 415. The first capacitance circuit 430 can have a short charge time and a long discharge time. The first resistance circuit 420 and first capacitance circuit 430 of the first complementary RC circuit 210 are designed to charge and discharge based on the input signal, generating an output signal of the first complementary RC circuit 210 at line 425.

The second complementary RC circuit 215 receives the output signal of the first complementary RC circuit 210 via line 425. The second complementary RC circuit 215 is designed to pass the output signal to the second resistance circuit 440 and second capacitance circuit 450 using the second P-path circuit 432 and second N-path circuit 435. The second capacitance circuit 450 is slowly charged by the second P-path circuit 432 and second resistance circuit 440, and is rapidly discharged by the second N-path circuit 435. The second capacitance circuit 450 can have a long charge time and a short discharge time. The second resistance circuit 440 and second capacitance circuit 450 of the second complementary RC circuit 215 are designed to charge and discharge based on the output signal of the first complementary RC circuit 210, generating the pulse width signal at line 217. The output driver 220 receives the pulse width signal via line 217 and maintains signal integrity of the pulse width signal at line 222.

FIG. 5 illustrates an embodiment of pulse width signals from a pulse width timing circuit 125, such as that shown in FIG. 4. The input signals at line 202 can include, but are not limited to, a square waveform that can be manipulated by the pulse width timing circuit 125 to provide the pulse width signal at line 222. At the rising end of a first square wave 525 at line 202, the first capacitance circuit 430 of the first complementary RC circuit 210 rapidly charges and the second capacitance circuit 450 of the second complementary RC circuit 215 rapidly discharge at lines 425 and 217, respectively. In this example, the pulse width signal at line 222 begins to rise at the midpoint 526 of the discharged signal of the second capacitance circuit 450 at line 217. The pulse width signal at line 222 is delayed by a delay time 505, which is measured from the midpoint of the rising signal of the square wave 525 to the midpoint 528 of the rising signal of the pulse width signal.

At the declining end of the first square wave 525 at line 202, the first capacitance circuit 430 of the first complementary RC circuit 210 slowly discharges, and the second capacitance circuit 450 slowly charges at lines 425 and 217, respectively. The pulse width 510 of the pulse width signal at line 222 is adjusted based on the discharged signal of the second capacitance circuit 450 at line 217. In this example, the pulse width signal at line 222 begins to decline at the midpoint 527 of the charged signal of the second capacitance circuit 450 at line 217. The pulse width of the pulse width signal at line 222 is measured between the midpoints 528, 529 of the rising and declining signals of the pulse width signal.

The above mentioned process is repeated for a second square wave 530, producing a delay time 515 and pulse width 520. By increasing the resistance and capacitance values of the first and second resistance circuits 420, 440 and capacitance circuits 430, 450, the pulse delay and the pulse width of the pulse width signal can be increased, and vice versa. By increasing the resistance values of the first and second resistance circuits 420, 440, the pulse width can be increased, and vice versa.

FIG. 6 is a more detailed block diagram that illustrates another embodiment of a pulse width timing circuit 125, such as that shown in FIG. 2. In this example, the architecture of the first complementary RC circuit 610 and the second complementary RC circuit 615 of FIG. 6 is similar to the architecture of the first complementary RC circuit 210 and the second complementary RC circuit 215 as described in FIG. 4. Like features are labeled with the same reference numbers, such as the first and second P-path circuits 410, 432, first and second N-path circuits 415, 435, and input and output drivers 205, 220. However, the first and second resistance circuits 420, 440 and the first and second capacitance circuits 430, 450 of FIG. 4 are implemented with first and second variable resistors 620, 640 and first and second variable capacitors 630, 650, as shown in FIG. 6.

In this example, the first and second variable resistors 620, 640 and first and second variable capacitors 630, 650 can be adjusted to vary the respective resistance values and capacitance values, affecting the delay and pulse width of the pulse width signal at line 222. The pulse width of the pulse width signal at line 222 can be fine-tuned with the first and second variable resistors 620, 640. Although FIG. 6 shows the variable resistors 620, 640, and variable capacitors 630, 650, they can be implemented with a combination of fixed resistors (not shown) and/or fixed capacitors (not shown). For example, the resistors can be variable with the capacitors fixed or the capacitors can be variable with the resistors fixed. The values of the fixed resistors and fixed capacitors can be determined in the design stage.

FIG. 7 is a more detailed block diagram that illustrates another embodiment of a pulse width timing circuit 125, such as that shown in FIG. 4. The first and second P-path circuits 410, 432, first and second N-path circuits 415, 435, the first and second resistance circuits 420, 440, the first and second capacitance circuits 430, 450 of FIG. 4, and the input and output drivers 205, 220 are shown with specific electrical components. For example, the first and second P-path circuits 410, 432, the first and second N-path circuits 415, 435 and the input and output drivers 205, 220 are implemented with first and second PMOS transistors 709, 742 and first and second NMOS transistors 740, 772, and invertors 705, 720, respectively. In addition, the first and second resistance circuits 420, 440 and the first and second capacitance circuits 430, 450 are implemented with first and second variable resistance circuits 708, 748 and first and second variable capacitance circuits 711, 751 in which their resistance values and capacitance values can be adjusted by a controller 225.

In this example, the first complementary RC circuit 703 includes a first CMOS inverter having the first PMOS and NMOS transistors 709, 740. The first CMOS inverter is coupled to a first RC circuit that includes first resistance and capacitance circuits 708, 711. The first variable resistance circuit 708 includes a first resistance ladder of resistors 724, 725, 727, 729 coupled in series. The resistors 725, 727, 729 are coupled in parallel with first NMOS switches 735, 737, 739, respectively, that facilitate adding or subtracting the resistors 725, 727, 729 from the resistance ladder to adjust the resistance value of the resistance ladder.

The first variable capacitance circuit 711 includes a plurality of first capacitors 717, 719, 721, 722 that are coupled in parallel and first PMOS switches 712, 714, 715 that are coupled between the first PMOS transistor 709 and the respective plurality of first capacitors 719, 721, 722. As capacitance adds in parallel, the first PMOS switches 712, 714, 715 facilitate adding or subtracting the first capacitors 719, 721, 722 from the parallel capacitors 717, 719, 721, 722 to adjust the capacitance value of the parallel capacitors 717, 719, 721, 722.

A similar approach is provided for the second variable resistance circuit 748 and second variable capacitance circuit 751. The second complementary RC circuit 704 includes a second CMOS inverter having the second PMOS and NMOS transistors 742, 772. The second CMOS inverter is coupled to a second RC circuit that includes second resistance and capacitance circuits 748, 751. The second variable resistance circuit 748 includes a second resistance ladder of resistors 754, 755, 757, 759 coupled in series. The resistors 754, 755, 757 are coupled in parallel with second PMOS switches 744, 745, 747, respectively. The second variable capacitance circuit 751 includes a plurality of second capacitors 765, 767, 769, 770 that are coupled in parallel and second NMOS switches 760, 762, 764 that are coupled between the second NMOS transistor 772 and the respective plurality of second capacitors 767, 769, 770.

The second PMOS and NMOS transistors 742, 772 receive the output signal of the first complementary RC circuit 703 at line 710. The controller 225 is coupled and configured to control the first and second PMOS switches 712, 714, 715, 744, 745, 747 using control signals at lines CS1-3 and S4-6 to adjust the total capacitance value and total resistance value of the first variable capacitance circuit 711 (through adding or subtracting the first capacitors 719, 721, 722) and the second variable resistance circuit 748 (through adding or subtracting the second resistors 754, 755, 757), respectively. The controller 225 is also coupled and configured to control the first and second NMOS switches 735, 737, 739, 760, 762, 764 using control signals at lines S1-3 and CS4-6 to adjust the total resistance value and total capacitance value of the first variable resistance circuit 708 (through adding or subtracting the first resistors 725, 727, 729) and the second variable capacitance circuit 751 (through adding or subtracting the second capacitors 767, 769, 770), respectively. It should be noted that the switches shown in FIG. 7 are PMOS and NMOS transistors, but can be implemented with any commercially available transistors.

The controller 225 can increase (or decrease) the delay and pulse width of the pulse width signal by adding (or subtracting) the first and second capacitors 719, 721, 722, 767, 769, 770. Similarly, the controller 225 can increase (or decrease) the pulse width of the pulse width signal by adding (or subtracting) the first and second resistors 725, 727, 729, 754, 755, 757. In this example, the control signals at lines S1-6 are the complement of the control signals at lines CS1-6. Thus, the controller 225 can include six output control codes and can receive at least 3 bits of input control codes. The controller 225 can be implemented as a mapping table that includes the six output control codes. The controller 225 determines which six output control codes to use based on the received 3 bits input control code and transmits the control signals at lines S1-6, CS1-C6 based on the determined output control code.

Although the invention has been described in terms of exemplary embodiments, it is not limited thereto. Rather, the appended claims should be construed broadly to include other variants and embodiments of the invention that may be made by those skilled in the art without departing from the scope and range of equivalents of the invention.

What is claimed is:

1. A pulse width timing circuit comprising:
a first complementary resistor-capacitor (RC) circuit having an input for receiving an input signal; and
a second complementary RC circuit coupled to an output of the first complementary RC circuit, wherein the first and second complementary RC circuits cooperate to produce an output signal based on the input signal, the output signal being delayed and having an adjusted pulse width with respect to the input signal.

2. The pulse width timing circuit of claim 1, further comprising a controller, said controller producing control signals for control of the pulse width timing circuit.

3. The pulse width timing circuit of claim 1, wherein the first complementary RC circuit includes a first inverter that is coupled to a first RC circuit, wherein the first RC circuit charges and discharges asymmetrically in response to the input signal.

4. The pulse width timing circuit of claim 3, wherein the first inverter includes a first P-path circuit and a first N-path circuit and the first RC circuit includes a first resistance circuit and a first capacitance circuit, the first resistance circuit being coupled between the first P-path circuit and first N-path circuit, the first capacitance circuit being coupled at a node between the first P-path circuit and first resistance circuit, wherein the first capacitance circuit is charged through the first P-path circuit and discharges through the first resistance circuit and first N-path circuit.

5. The pulse width timing circuit of claim 4, wherein the second complementary RC circuit includes a second inverter that is coupled to a second RC circuit, wherein the second RC circuit charges and discharges asymmetrically in response to an output signal of the first complementary RC circuit.

6. The pulse width timing circuit of claim 5, wherein the second inverter includes a second P-path circuit and a second N-path circuit and the second RC circuit includes a second resistance circuit and a second capacitance circuit, the second resistance circuit being coupled between the second P-path circuit and second N-path circuit, the second capacitance circuit being coupled at a node between the second resistance circuit and second N-path circuit, wherein the second capacitance circuit is discharged through the second N-path circuit and charged through the second resistance circuit and second N-path circuit.

7. The pulse width timing circuit of claim 6, wherein the first and second P-path and N-path circuits include PMOS transistors and NMOS transistors, respectively.

8. The pulse width timing circuit of claim 6, wherein the first and second resistance and capacitance circuits include resistors and capacitors, respectively.

9. The pulse width timing circuit of claim 6, wherein the first and second resistance and capacitance circuits include variable resistance circuits and variable capacitance circuits, respectively.

10. The pulse width timing circuit of claim 9, wherein the first and second variable resistance circuits each include a plurality of selectable resistors coupled to a switching circuit, whereby the resistances of the variable resistance circuits is adjusted.

11. The pulse width timing circuit of claim 9, wherein the first and second variable capacitance circuits each include a plurality of selectable capacitors coupled to a switching circuit, whereby the capacitances of the variable capacitance circuits is adjusted.

12. The pulse width timing circuit of claim 9, further comprising a controller coupled to the variable resistance circuits and variable capacitance circuits to adjust the resistance value and capacitance value of the variable resistance circuits and variable capacitance circuits, respectively.

13. A digital logic circuit comprising:
a first complementary resistor-capacitor (RC) circuit having an input for receiving an input signal, the first complementary RC circuit providing a first adjustment to a timing and a pulse width of the input signal, thereby providing an adjusted input signal; and
a second complementary RC circuit having an input coupled to an output of the first complementary RC circuit, the second complementary RC circuit providing a second adjustment to a timing and a pulse width of the adjusted input signal,
an output driver coupled to an output of the second complementary RC circuit.

14. The digital logic circuit of claim 13, wherein the first complementary RC circuit charges and discharges asymmetrically in response to the input signal.

15. The digital logic circuit of claim 14, wherein the first complementary RC circuit charges faster than it discharges in response to the input signal.

16. The digital logic circuit of claim 15, wherein the second complementary RC circuit charges and discharges asymmetrically in response to the adjusted input signal.

17. The digital logic circuit of claim 16, wherein the second complementary RC circuit charges slower than it discharges in response to the adjusted input signal.

18. A method of producing a pulse width signal in response to an input signal, comprising:
receiving an input signal;
providing a first adjustment to a timing and a pulse width of the input signal;
after providing the first adjustment, providing a second adjustment to a timing and a pulse width of the input signal; and
after providing the second adjustment, producing a pulse width signal from the input signal.

19. The method of claim 18, wherein the providing the first adjustment step includes the step of providing the input signal to a first complementary RC circuit configured for asymmetric charging and discharging in response to the input signal.

20. The method of claim 19, wherein the providing the second adjustment step includes the step of providing the input signal to a second complementary RC circuit configured for asymmetric charging and discharging in response to the input signal, wherein the first and second complementary RC circuits are oppositely asymmetric with respect to their charging and discharging.
